(19) United States
(12) Patent Application Publication
(10) Pub. No.: US 2008/0123771 A1
(43) Pub. Date: May 29, 2008

(54) Systems and Arrangements for Controlling an Impedance on a Transmission Path

(75) Inventors: Hayden C. Cranford, Cary, NC (US); Daniel J. Friedman, Sleepy Hollow, NY (US); James S. Mason, Eastleigh (GB); Martin L. Schmatz, Rueschlikon (CH); Michael A. Sorna, Hopewell Junction, NY (US); Thomas H. Toifl, Zurich (CH)

Correspondence Address: IBM COPORATION (RTP);C/O SCHUBERT OSTERRIEDER & NICKELSON PLLC, 6013 CANNON MOUNTAIN DRIVE, S14, AUSTIN, TX, 78749, US

(73) Assignee: INTERNATIONAL BUSINESS MACHINES CORPORATION, Armonk, NY (US)

(21) Appl. No.: 11/557,676

(22) Filed: Nov. 8, 2006

(51) Int. Cl. H04B 15/00; H03H 7/40

(52) U.S. Cl. 375/285; 333/17.3

(57) ABSTRACT

Systems for making impedance adjustments that will auto-tune a communication path is disclosed. The method can utilize time domain reflectometry (TDR) to acquire data about impedance mismatches and can adjust the termination impedances based on the acquired data. A system is also disclosed that has an isolator to decouple a first adjustable resistor from a transmission path in a first mode and couple the first adjustable resistor to the path in a second mode. The system can have a test transmitter to create a first current on the path in the first mode and to create a second current having twice the current in a second mode, wherein a detector can detect a first voltage during the first mode and a second voltage in the second mode as the first adjustable resistive load is adjusted in the second mode until it reaches a value matching the first voltage detected in the first mode.

### FIELD OF INVENTION

The present disclosure is related to the field of signal propagation and more particularly to the field of impedance matching for a communication system transmission path.

### BACKGROUND

High-speed serial communication links are often utilized to convey data from integrated circuit to integrated circuit or from “chip-to-chip.” A basic system can have a transmitter that is integrated on the chip, which can send data over the transmission path, such as a transmission line, wherein the transmitted data can be acquired by a receiver. In state-of-the-art communication systems, transmitters and receivers are often placed in an integrated circuit and integrated with other functional sub-systems systems on the chip, to minimize the space required to implement a communication system. The transmission path can include conductive media such as a backplane, a cable or a printed circuit board.

The printed circuit board can be made of many different materials including a fire retardant group four (FR4) material. The on-chip transmitter and receiver typically terminate the transmission path with some form of resistance matched to the wave impedance of the transmission medium in order to reduce reflections. To maximize performance, the value of the termination resistor is carefully selected, but component and manufacturing tolerances can skew this resistance value. Further, unwanted and unavoidable parasitic load capacitances are typically present at numerous locations along the transmission path.

Such capacitances are typically distributed throughout components of the communication system. The parasitic capacitance is a result of inherent properties of materials utilized in components of the transmitter, receiver and the materials utilized in the manufacture of the transmission lines. For example, the silicon in the receiving transistors and transmitting transistors, the copper in the transmission line and the materials utilized in the electrostatic-discharge (ESD) protection devices in the transmission path all contribute to this undesirable capacitance and resistance. The capacitance becomes a significant problem at higher frequencies and such capacitance can distort the data waveform from its intended shape such that the data on the waveform becomes unreadable by a receiver.

In operation, “high-speed,” Gigahertz digital data transmissions can be viewed with a data analyzer that can trace continuous data waveforms across a display screen. A transmission path between a transmitter and a receiver that is terminated with the proper impedance will provide a display of waveforms that has a series of eye patterns. A transmission path that has impedance mismatches, or terminations that do not match the impedance of the transmission path will have distorted eye patterns or eye patterns that are smaller and less defined. When such distortion occurs, it is difficult to read data or recover data from the incoming waveform.

When significant impedance mismatches occur within the transmission path, the desirable eye pattern shape can be so small that the clock data recovery circuitry can get out of synchronization with the waveform. Correspondingly, the clock data recovery system can misread data in the data stream. Accordingly, it is important to terminate a transmission path such that data can be successfully transmitted in the Gigabit range.

One reason that the traditional “eye pattern” can become distorted is that when a transmitted wave encounters an impedance mismatch at the termination, a portion of the wave can be reflected back to the transmitter, while a portion of the wave is absorbed by the receiver. Energy will also be reflected at every impedance mismatch along the transmission path. Therefore, when multiple mismatches occur not only is the shape of the eye patterns distorted but also random noise, cross talk and interference in general is generated by the mismatches and such phenomenon significantly degrades the quality of the communication link.

In order to maximize the quality of the received signal and the quality of eye patterns created by the signal, a designer must calculate all of the tolerances that create reflections of the signal at the transmitter output and the receiver input due to impedance mismatches. In even the best designs, uncontrollable production and component tolerances can cause “out of box” failures of equipment. Even though it is desirable to match impedances on the transmission path by closely matching the termination impedance to the actual transmission line impedance, different manufacturing process and vendors that may supply components often have impedances that are out of tolerance.

It can be appreciated that a significant amount of newly assembled systems that have impedance mismatches will not perform at the intended data transfer speeds due to transmission path problems. Thus, it would be desirable to have a way to compensate for component tolerances manufacturing tolerances and other manufacturing and design flaws without requiring a technician to test and tune every circuit before it is packaged for sale. For example, it would be beneficial if devices that communicate could provide “Plug and Play” functionality where the impedance mismatches could be minimized by an auto-tuning circuit.

### SUMMARY OF THE INVENTION

The problems identified above are in large part addressed by the systems, methods and media disclosed herein to provide a system for making impedance adjustments that will auto-tune a transmission path for a communication system or any system that can move data from one location to another. The method can utilize time domain reflectometry (TDR) to acquire data about impedance mismatches and can adjust the termination resistances and reactances based on the acquired data. In one embodiment the method can include transmitting electrical energy on a transmission path and utilizing a time sampling routine to detect reflected energy resulting from the transmitted energy.

The method can detect the magnitude and time delay of the reflected energy to determine where the tuning will take place, and how much resistance or reactance will be added or subtracted to the transmission path to “tune out” the unwanted reflection. Multiple tunable impedance modules can be placed at various locations along the transmission path and the detected time delays of the reflected energy can be utilized to determine which tunable impedance module will be controlled. A tuning module can determine the actual adjustment or change in impedance value to be made based on the magnitude of the reflection and control the tunable impedance module according to this determination.

Thus, the termination impedances of a transmission path can be automatically adjusted proximate to the impedance mismatch responsive to the determined characteristic of the reflected energy. The electrical energy can be in the form of a pulse with a predetermined pulse duration such that the reflected energy returns prior to the end of the duration of the pulse and alters a voltage of the pulse such that a voltage deflection of the pulse can be determined by a comparator that is triggered by a timer.

In one embodiment, the system, apparatus and method can detect a maximum deflection of, or change to, the pulse voltage by the reflected wave energy. The impedance can be automatically adjusted by a resistance, a capacitance or an inductance termination to the transmission path. The transmitted electrical energy can manifest in the form of a pulse with a predetermined pulse duration such that during the duration of the pulse a resistive and a reactive reflection can be detected. Pulses of varying frequencies can be transmitted and frequency responses could be identified. In addition, a distance between the transmitter and the impedance mismatches can be determined by acquiring different time amplitude samples of the reflected wave utilizing known information about the propagation velocity of the energy within the transmission path.

In another embodiment a transmission line tuning apparatus is disclosed. The apparatus can include a transmission path having a first connection proximate to a first transmitter termination and a second connection proximate to a second termination that is proximate to a receiver. The apparatus can include a transmitter coupled to the first connection to transmit a test signal over the transmission path and a tunable impedance module coupled to the transmission path proximate to the second termination. An impedance tuning module can be coupled to the tunable impedance module and to the transmission path to monitor reflected signal energy on the transmission path resulting from the test signal. Impedance tuning module can control the tunable impedance module in response to the monitored reflected signal energy such that changing a setting of the tunable impedance module can reduce the reflected signal energy and improve the performance of the communication link.

The apparatus can also include a compare module, coupled to the transmission path, to detect a direction of difference in voltage and a magnitude that the reflected signal energy causes. According to such a determination, a resistance and reactance of the tunable impedance module can be changed. The adjustment in impedance can be made and additional pulses can be transmitted as the mismatch is tuned out during the auto-tuning process. The tunable impedance module can be implemented with switches that can switch in a resistor ladder network and can switch a T-coil having to a desired capacitance into the system. Such a tunable impedance module can tune out impedance mismatches near a termination of the transmission line.

In yet another embodiment, a communication system with a tunable transmission line is disclosed. The system can include a transmission line, a transmitter to transmit electrical energy over the transmission line, and a detector coupled to the transmission line to detect reflected energy resulting from the transmitted energy. The system can also include control logic coupled to the detector to determine an impedance change in the transmission line based on parameters of the reflected energy, and a tunable impedance module coupled to the control logic and the transmission line to automatically change a termination impedance of the transmission line responsive to the output of the control logic.

The system can further include a test transmitter located proximate to the receiver and a second tunable impedance module coupled proximate to the transmitter. The test transmitter can test the tuning of the transmitter and the second tunable impedance module can be controlled to change an impedance proximate to a transmitter end of the transmission line based on the reflected signal test described above. The impedance can be changed by a tunable inductor, a tunable capacitor, or a resistor network that can change values based on a control signal.

In a particular embodiment, a communication system is disclosed that has an isolator to decouple a first adjustable resistive load from a transmission path in a first mode and to couple the first adjustable resistive load to the transmission path in a second mode. The system also has a test transmitter to create a first current on the transmission path in the first mode and to create a second current on the transmission path in a second mode, wherein the second current is approximately twice the first current. A detector can be coupled to the transmission path to detect a first voltage on the transmission path during the first mode in response to the first current and to detect a second voltage substantially similar to the first voltage responsive to the second current in the second mode. The system can also include a control logic module responsive to the detector to adjust a resistance of the first adjustable resistive load during the second mode.

In a specific embodiment a method of tuning a circuit can include increasing an impedance of a first termination impedance to limit a first current to flow through the first termination impedance. A second current can be provided through a second termination impedance and a first voltage can be detected that is associated with the second current, and a value of the first termination impedance can be adjusted, and a third current can be provided which is a combined current through the first and second termination impedances. The second voltage can be detected responsive to the third current and the value of the first termination impedance can be adjusted such that the second voltage substantially matches the first voltage.

### BRIEF DESCRIPTION OF THE DRAWINGS

Aspects of the invention will become apparent upon reading the following detailed description and upon reference to the accompanying drawings in which, like references may indicate similar elements:

FIG. 1 depicts a block diagram of a communication system;

FIG. 2 depicts a graphic of how a reflected wave can affect a pulse;

FIG. 3 illustrates a block diagram of transmission path tuner;

FIG. 4 illustrates a variable reactance tuning circuit;

FIG. 5 depicts another variable reactance tuning circuit;

FIG. 6 illustrates a flow chart for tuning a resistance of a transmission line; and

FIG. 7 illustrates another flow chart for tuning a transmission line.

### DETAILED DESCRIPTION OF EMBODIMENTS

The following is a detailed description of embodiments of the disclosure depicted in the accompanying drawings. The embodiments are in such detail as to clearly communicate the disclosure. However, the amount of detail offered is not intended to limit the anticipated variations of embodiments; on the contrary, the intention is to cover all modifications, equivalents, and alternatives falling within the spirit and scope of the present disclosure as defined by the appended claims. The descriptions below are designed to make such embodiments obvious to a person of ordinary skill in the art.

While specific embodiments will be described below with reference to particular configurations of hardware and/or software, those of skill in the art will realize that embodiments of the present invention may advantageously be implemented with other equivalent hardware and/or software systems. Aspects of the disclosure described herein may be stored or distributed on computer-readable media, including magnetic and optically readable and removable computer disks, as well as distributed electronically over the Internet or over other networks, including wireless networks. Data structures and transmission of data (including wireless transmission) particular to aspects of the disclosure are also encompassed within the scope of the disclosure.

In accordance with the present disclosure a tuning module can make or control impedance adjustments for a high-speed serial link utilizing data obtained from time-domain-reflectometry (TDR) such that improved communication performance can be achieved. Further, the disclosed embodiments are applicable to Gigahertz digital data transmission from chip-to-chip over relatively short transmission paths. One method for achieving impedance matching is to utilize time domain reflectometry measuring and testing for improving path performance and automatically adjust a tuning element on the transmission path to compensate for impedance mismatches. Such compensation can be done automatically without human intervention. This feature can eliminate the requirement to equip devices with a trimming component and the requirement to manually test equipment on the production floor.

In accordance with the present disclosure, a tuning module can perform as a “mini network analyzer” and can determine the attributes of a mismatch on a transmission path utilizing TDR. The tuning module can then control a controllable tuning module to adjust a tunable termination impedance on the transmission path to correct problematic impedance mismatches in the transmission path. In response to detected TDR data, the tuning module can control solid state tunable elements such as inductors and capacitors or the tuning module can control miniature electrical mechanical systems (MEMS) to tune or trim the transmission path such that a communication network can achieve maximum communication performance. The traditional manual or customized trimming process for production circuits is a very expensive and unreliable and the systems and methods of the present disclosure can eliminate such a process.

Generally, a reflection of an electromagnetic wave can be thought of as an “echo” where a wave, which has been generated, is reflected at one or more points along the transmission medium. The different points or locations along the transmission line will typically reflect different magnitudes of energy such that the magnitude and time of the detected reflections can be determined by the tuning module. Such reflections can be identified by the tuning module in some manner as a wave distinct from that of the main, primary or original transmission.

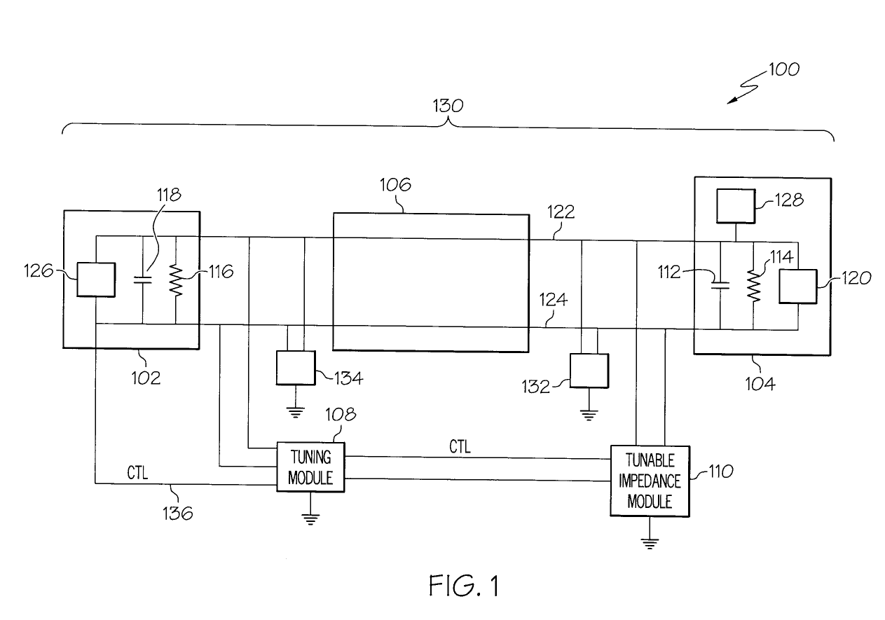

Referring to FIG. 1 a communication system such as a communication link 100 is disclosed. Although a digital communication link is illustrated an analog radio frequency system could also utilize the teaching disclosed herein. The system 100 can include a transmitter 102, a receiver 104, and a channel or transmission line 106. The system can also include a transmission path 130 that includes all paths in the system in which an electromagnetic wave generated by the transmitter 102 can travel. The transmission path 130 can have various mediums made with different materials and impedance mismatches will occur at interfaces between the different mediums. The transmission line 106 can provide a homogenous impedance that interconnects the transmitter 102 with the receiver 104 and thus, a tunable impedance module may not be needed in all locations along a homogeneous transmission line 106.

Tunable impedance modules such as tunable impedance modules 110 and 134 can be placed where changes in the medium of the transmission path are most likely and where terminations of the transmission path 130 occur. Tuning modules 108 and 132 can control tunable impedance modules 110 and 134 respectively to “tune out” impedance mismatches in the transmission path 130. To achieve such impedance matching, the tuning module 108 can utilize time-domain reflectometry (TDR) during a tuning process and control and adjust an impedance value provided by the tunable impedance module 110 to achieve such impedance matching. Such tuning can significantly improve communication performance in systems that transmit digital data in the multi Gigabit per second range over relatively short electrical links.

The transmission line 106 can carry differential data and can have a data line 122 and a complementary data line 124 such that when one line provides a logic high value the other line provides a logic low value. In one embodiment, the receiver 104 can provide a target termination impedance value of fifty (50) Ohms illustrated by resistor 114. Capacitor 112 illustrates any parasitic capacitance that may be present in the receiver 104. The receiver 104 can perform clock and data recovery with the assistance of clock and data recovery circuit 120. The transmitter 102 can have an output impedance of fifty (50) Ohms illustrated by resistor 116, and the receiver 104 can have a termination impedance of fifty (50) Ohms, such that the system has impedance matched components. As stated above, although impedance matching is a design goal, in reality many factors can, and do create impedance mismatches causing degraded communication. Capacitor 118 illustrates the parasitic capacitance often present proximate to the transmitter 102. The transmitter 102 can have a power transistor 126 for transmitting electrical energy, possibly modulated and containing data.

The transmission path 130 can be implemented as one of, or a combination of, traces or striplines on a printed circuit board, a variety of connectors, pins, plated through holes, integrated circuit packages, wire bonds and other interconnection hardware. The transmission line 106 can include, backplane wiring and many types of cabling. Such hardware can provide impedances that are fairly well matched to the input and output impedance of the transmitter 102 and the receiver 104 but some impedance mismatch is virtually inevitable. Manufacturing tolerances and other material mismatches may provide termination impedances that are above, or below the desired impedance. Accordingly, in one embodiment, tuning module 108 can be placed proximate to the transmitter 102 and can instruct the transmitter 102 via control line 136 to transmit test pulses to the receiver 104. The tuning module 108 can detect the magnitude and polarity of the reflected wave and control tunable impedance module 110 to “adjust out” or tune out impedance mismatches at the receiver termination. Thus, noise and/or reflections on the transmission path 130 can be minimized and data signals can travel over the transmission path to the receiver without significant degradation.

The tuning module 108 can also determine many other characteristics of the transmission medium or transmission path 130. For example, in one embodiment, the tuning module 108 can be utilized to determine a status of the transmission path 130 including whether the path 130 has an open or a short including connectivity to an appropriate load (i.e. connected or not connected) or a quality of connectivity. Such a determination may be reported to a diagnostics system (not shown) or a processor that controls the transmitter 102 (not shown) such that appropriate changes can be made. The tuning module 108 can also be utilized to determine the length of the transmission path 130. The determined length may be utilized to determine an optimum speed at which data can be transmitted within the system. Thus, the test results and output provided by the tuning module 108 regarding characteristics about the transmission path 130 determined through detection (or non-detection) of a return signal (e.g., a reflection) can be utilized by other components in the communication system 100 to improve performance.

The illustrated system 100 provides two tunable impedance modules 110 and 134, however, additional impedance modules could be placed anywhere in the system 100 and particularly where the transmission medium along the transmission path 130 may change. Generally, electrical energy in the form of waves containing data can be generated by power transistor 126 and can travel to receiver termination 120, where data from the electromagnetic wave can be extracted by the clock and data recovery system 120. As stated above, every transition along the path that has an interface with different materials or material compositions, will reflect some wave energy. For example, when the wave moves from a pin of an integrated circuit to plated through hole and to a trace of circuit board and to the termination of the receiver 104 all of these interfaces will have some impedance mismatch and will reflect a portion of the power in the wave back to the transmitter 102. Thus, one location for placement of tunable impedance module 110 can be to integrate the tunable impedance module 110 on the same integrated circuit, and proximate to the termination resistor 114 of the receiver 104.

In accordance with one embodiment, the tuning module 108 can be placed proximate to the receiver 104 and can tune the transmission path, possibly near the receiver termination such that minimal reflection will occur from this termination and a high quality data waveform can be present on the transmission path 130 at all locations, at all times. The tuning can be done as part of a power up procedure. In such a procedure, the transmitter 102 could transmit electrical energy possibly in the form of a pulse or possibly a specific bit pattern and the tuning module 108 can analyze the waveforms on the transmission path 130 to determine what impedance at what locations will change the tuning of the transmission path 130.

Once the tuning module 108 has determined the amount of, and the location of, the reflection an appropriate remedy can be determined by the tuning module 108. Accordingly, the tuning module 108 can control one or multiple tunable impedance modules (such as tunable impedance module 110) throughout the transmission path 130, to minimize the amount of reflected energy traveling along the transmission path 130. The tunable impedance module 110 can be a variable capacitor and/or a variable “T-coil” to adjust the termination impedance. Also a fixed T-coil with a variable capacitor could be utilized. In other embodiments, a single parallel or series connected element which is adjustable could be utilized to control the total inductance.

In one embodiment, the tuning procedure can start with the transmitter 102 transmitting a “rectangular” or substantially rectangular pulse to the receiver 104 over the transmission line 106. The magnitude of the impedance mismatch can be determined by sampling the amount of reflected signal at an appropriate time. If the transmitter 102 has a poor impedance match, the “returning” wave from the receiver 104 may again bounce of off the transmitter 102 and distort subsequent signals. The waveform energy on the transmission line 106 may cancel some the energy under current transmission or can add to current transmission depending on the phase and direction of the wave. Thus, impedance mismatches can severely degrade the communication process.

To minimize such interference caused by reflections off of the transmitter termination, impedance mismatches at the terminations can be “tuned out.” To accomplish this, the receiver 104 can have a test transmitter 128, that can transmit a test pattern of bits or pulses to the termination of the transmitter 102, and a tuning module 132 proximate to the receiver 102 can adjust tunable impedance module 134 such that reflections from impedance mismatches proximate to the transmitter 102 can be tuned out, and the transmitter termination can achieve an impedance match.

After the transmission path 130 is tuned by tunable impedance modules 110 and 134, then a high quality waveform containing digital data can be transmitted from the transmitter 102 to the receiver 104. A high quality waveform with a high quality eye patterns allows for higher data speeds and improved data error rates for digital communications. The tuning modules 108 and 132 can adjust the termination impedance of a transmitter 102 and receiver 104 such that noise levels and interference from reflected waves are reduced and improved data rates with lower error rates can be achieved.

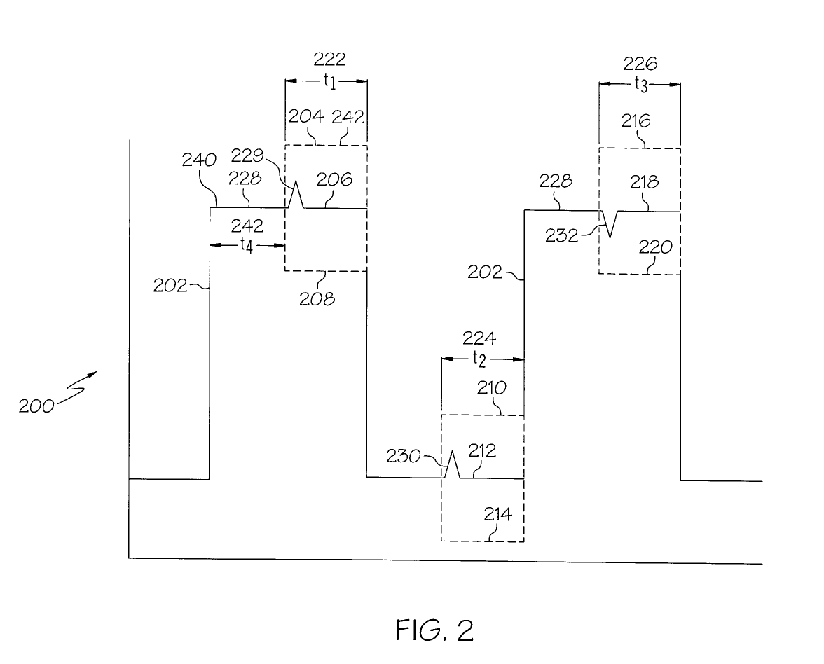

Referring to FIG. 2, a graphical representation 200 of responses to step pulses on a transmission path are illustrated. The vertical axis reveals a voltage response to a pulse on the transmission path and the horizontal axis provides a progression of time during a tuning process. The distortion during t1 222, t2, 224 and t3 226 of the pulse waveforms illustrates how reflected waves from impedance mismatches can affect the output signal of a transmitter. Accordingly, impedance mismatches that are causing such distortions can be detected and corrected by the auto tuning system of the present disclosure. Three different waveforms have been superimposed on the graph where the waveforms are equivalent during most of each cycle but the three waves diverge during time periods t1 222, t2, 224 and t3 226.

Generally, the graph 200 represents pulses sent by a transmitter with leading edges 202 and the steady state plateau value 228. Then, during time periods t1 222, t2 224 and t3 226, pulse energy reflected from impedance mismatches has returned to the location of the voltage sensor or detector and distorted the pulse or the output of the transmitter either up, as illustrated by waves 204, 210 and 216, or down, as illustrated by waveforms 208, 214 and 220. When a reflection due to a mismatch at a resistive termination does not occur, the pulse will remain relatively constant as shown by waveforms 206, 212 and 218. If the reflected wave increases the voltage of the pulse (as in waveform 204) this typically indicates that the resistance at the termination is too large as the reflected wave is adding energy to the pulse. Likewise, if the reflected wave decreases the voltage of the pulse (as in waveform 208) this is an indication that the impedance at the termination is too small, as the reflected wave subtracts energy from the pulse.

The tuning system can also determine the length of the transmission line by detecting when the reflected energy returns to the tuning module. Accordingly, the pulses that are transmitted on an impedance matched line will remain relatively square as illustrated by waveform 206 during t1 222, waveform 212 during t2 224, and waveform 218 during t3 226. Waveforms 204, 210 and 216 can represent a waveform on a 50 Ohm transmission path that has a 75 Ohm resistive impedance, while waveforms 208, 214, and 220 can represent waveform on a 50 Ohm transmission path that has a 25 Ohm termination impedance, and waveforms 206, 212 and 218 can have a transmission path with a termination impedance of 50 Ohms. The graph illustrated utilizes 50 Ohms because many Gigabit digital transmission systems utilize 50 Ohms to terminate the transmission lines. As stated above, it is desirable for the square wave to maintain a square shape because this indicates that the energy from a reflected wave is minimal.

To detect impedance mismatches in the transmission path, the tuning system can sample the voltage of the pulse when it first stabilizes such as at time 240 and then sample the pulse during the distortion (i.e. in the example during time periods t1 222, t2 224 and t3 226). Thus, the tuning system should sample the voltage on the transmission line before the transmitter transitions to the next pulse. The waveform can be sampled by a comparator that is clocked such that the comparator samples the voltage on the transmission line multiple times per pulse. The output of the comparator can be stored in a register and utilized by control logic to re-tune the path. The time (t4 242) it takes for the distortion of the pulse to occur, as determined by the comparator, can be utilized by the logic module to determine the length of the transmission line or the location of impedance mismatch. In one embodiment, the amount of the mismatch that is occurring can be accurately measured by determining when the distortion of the pulse is at its maximum.

The system and method of the present disclosure can provide both resistive and reactive tuning. Once the termination resistance is determined and the proper termination resistance is applied to the system, there may still be energy reflected by an unwanted reactance at the termination end. This parasitic reactance can manifest as a noise or a notch such as notches 229, 230 and 232. These notches 229, 230 and 232 can be caused by reflections off of the reactive materials in the transmission path. Often, this is a result of a parasitic capacitance of the receiver. The tuning system of the present disclosure can also be utilized to adapt the termination such that the reactance or parasitic capacitance is matched. This may require adjusting the value of a reactive element proximate to the receiver termination.

As stated above, waveforms 208, 210 and 216 illustrate a receiver that has a termination impedance that is smaller or less than the transmission line impedance, hence V(Δt2)<V(Δt1). Waveforms 204, 214, and 216 illustrate a receiver with a termination impedance that is higher than the transmission line impedance. Waveforms 206, 212 and 218 depict the case that the receiver termination impedance is relatively well matched with the impedance of the transmission line. Hence, by determining the difference between V(Δt1) at 240 and V(Δt2) at 242, a tuning system can provide the proper adjustment to a termination impedance at a specific location. It may take several iterations or several tuning points may be attempted by the system before the tuning system provides an acceptable impedance mismatch or setting of tunable impedance modules at desired locations to “tune” out mismatches such that improved communications parameters can be achieved.

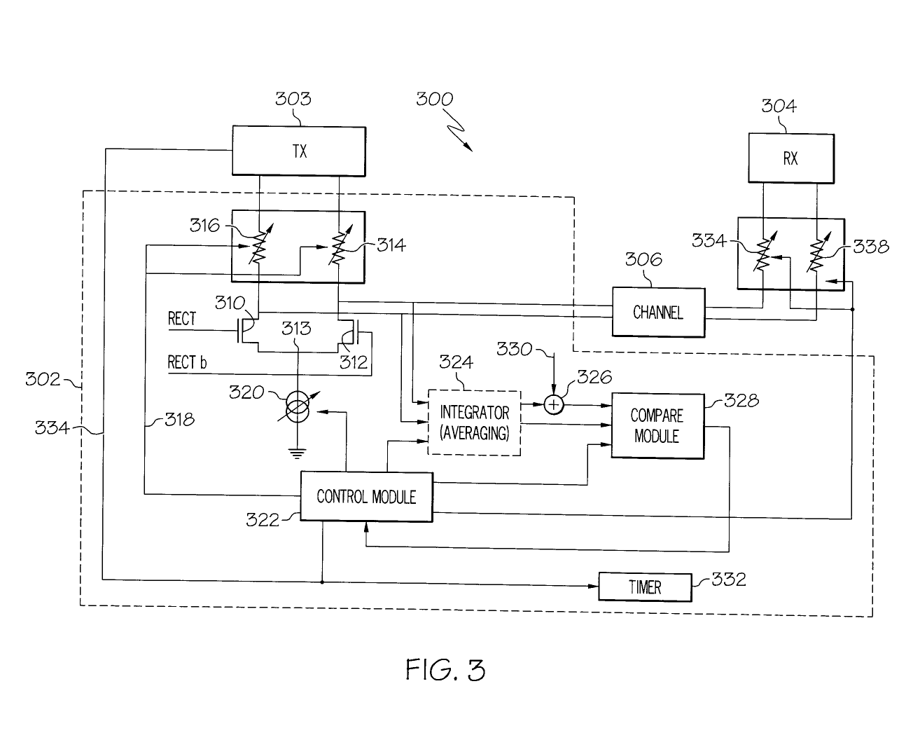

Referring to FIG. 3, a more detailed block diagram of a tuning system 302 coupled in a communication system 300 is disclosed. The tuning system 302 can be connected to a transmitter 303, a receiver 304 and a transmission line 306. The transmission line 306 can interconnect the transmitter 303 to the receiver 304. The tuning system 302 can include transistors 310 and 312 configured as a differential pair 313, adjustable impedance elements 314 and 316 on a transmission end, adjustable current sink 320, control module 322, an integrator 324, a voltage adder 326, a clocked compare module 328 and adjustable impedance elements on a receiver end 334 and 338.

It can be appreciated that when a communication system 300 is newly assembled that impedance mismatches, stray capacitance, transmission line lengths, supply voltage levels and other tolerance related phenomena can adversely affect the communication performance of the system 300. Thus, an auto-correction tuning system, apparatus and method that can compensate for these manufacturing tolerances and automatically correct deficiencies caused by such tolerances can improve the quality of the communication link. The tuning system 302 of the present disclosure can adapt the termination impedance of the transmitter 303 and the receiver 304 to increase the amount of signal power that is useable by the receiver 304 and decrease the amount of signal power that is lost or unusable and contributes to interference.

In one embodiment, the tuning system 302 can tune the communication system 300 such that the transmitter 303 and receiver 304 can exchange data at rates in excess of three Gigabits per seconds with minimal data error rates. At such high data rates accurate reading of the data requires the receiver 304 to synchronize with the transmitter 303 such that the data can be properly sampled. Such synchronization can be easily accomplished when clean waveforms are present within the transmission line. A “tuned” circuit that has minimized impedance mismatches allows the receiver 304 to accurately synchronize and read data and will increase the accuracy of the received data and reduce the error rate of the communication.

In accordance with a specific embodiment, the control module 322 via control line 334 can instruct the transmitter 303 to transmit a test pulse or wave over the transmission line 306 to the receiver 304. The output circuitry of the transmitter 303 can be configured as a current-mode logic (CML) amplification stage and such a stage can generate the required step pulse. If the transmission path is not terminated appropriately, the transmitted wave will be reflected by impedance mismatches. Mismatches often occur at the termination provided by the receiver 304. The transmitter 303 can maintain the pulse voltage until the reflection from the mismatch at the receiver 304 returns to the integrator 324 and compare module 328, distorting the pulse being transmitted over the transmission path. The magnitude of the pulse can be determined when it first achieves a steady state as the control module 322 triggers the compare module 328 via a clock or timer 332 to acquire the measurement. The compare module 328 can be a detector that detects voltage levels on the transmission line. The magnitude of the pulse can be determined at a later time, responsive to a signal from the timer 332, when return energy from the impedance mismatch distorts the pulse. Such time delays can be determined by taking samples or by continuously monitoring the transmission path for distortion.

To measure the magnitude of the pulse and the distortion of the pulse, the voltage on one of the inputs of the compare module 328 can be raised or lowered by providing an adjustable offset voltage 330 to voltage adder 326. Raising and/or lowering the offset voltage 330 can adjust the voltage at which the compare module 328 will trigger, indicating to the control module 322 that a voltage has been detected on the transmission path that is greater than or less than the offset voltage. Thus, the compare module 328 can measure and/or determine the magnitude of the pulse, the effect of the reflected wave on the pulse, the time which it takes a reflection to return and the distance from the transmitter that the impedance mismatch occurs.

These two measurements can be utilized by the control module 322 to determine the characteristics of the mismatch, (the type and amount of the resistance or reactance) such that the control module 322 can control the tuning elements 316, 314, 334 and 338. Tuning elements 314, 316, 334 and 338 can be purely resistive, purely reactive or a combination or both. Further the tuning elements 314, 316 334 and 338 can be purely solid state devices, (i.e., transistors variable capacitors or they can include miniature electrical mechanical systems (MEMS). In one embodiment, tuning elements 314, 316, 334 and 338 could be individually “mis-tuned” such that their location can be identified utilizing TDR. Once their location is determined, then the control module 322 can select the tuning element closest to a detected mismatch for adjustment.

As stated above with reference to FIG. 1, a second control module (not shown) could monitor the receiver end of the path and control variable impedances 314 and 316. Accordingly, the output impedance of the transmitter 303 can be adjusted in a similar manner by sending an impulse from a test transmitter built into the receiver 304 and a tuning system could measure the energy reflected back from the transmitter 303 and adjust tuning elements 314 and 316.

In one embodiment, to initiate the tuning process, the transmitter 303 can place a DC voltage on the transmission path and the offset voltage ΔVₛ330 can be adjusted until the output of the compare module 328 flips or changes state, then the transmitter can transmit pulses. The output voltages V(Δt_{1,2,3} . . .) of the compare module 328, at time offsets Δt1, Δt2 etc, can be provided to the control module 322 and the control module can utilize this plurality of time-amplitude data points to determine a voltage current slope and provide control signals to the tuning modules according to the data. This measurement process can be repeated for different values of Δt, allowing the control logic 322 to acquire, store and derive the reflection properties over the entire length of the transmission path.

In another embodiment, the tuning system 302 can begin by adjusting the impedances 334 and 338 at the receiver termination only. In this embodiment, a measurement at two discrete times can be sufficient to provide the appropriate tuning information to the control module 322. For example, at times Δt1 and Δt2 as determined by timer 332, the compare module can acquire useful tuning data. Time interval Δt1 can be a relatively small time interval that triggers acquisition of the pulse amplitude quickly after the launch of the pulse from the transmitter 303, and Δt2 can be a time interval that is chosen, such that the reflected wave from the receiver 306 is present at the termination of the transmitter 304. Then, the distortion of the pulse or change in voltage of the transmitter output voltage can again be measured or determined to indicate how much reflected energy has returned to the transmitter 303. A bit error rate measurement taken at the transmitter 303 could also be provided to the control module 322 to determine how changing the impedance of the transmission line affects the data error rate.

The offset voltage 330 can be added to the voltage present on the transmission line via the integrator 324. The voltage adder 326 can accept a programmable offset voltage ΔVₛ 330. The programmable offset voltage can be generated based on the signal technology or logic levels of the system and based on the anticipated reflection energy. The integrator 324 can operate as a low pass filter, and can filter out high-frequency noise that may be present on the transmission line 306. Thus, the voltage created by a test pulse on the transmission line 306 can be applied to the input of the clocked compare module 328. The clocked compare module 328 can take samples of the voltage at the output of the transmitter 303 at a defined time “Δt” defined in response to a signal from the timer 332 after the step impulse has been transmitted by the transmitter 303. The step pulse can be launched or transmitted periodically, and the tuning system 302 can measure the responses of the communication system 300.

The test pulse can be transmitted often, and the tuning process can be repeated many times until an acceptable communication system tuning is achieved. During such a “calibration” or tuning process the system 300 can achieve greater and greater accuracy as some of the testing parameters can be adjusted by the control module 322 such that an impedance mismatch, or impedance mismatches can be determined. As stated above, different bit patterns can be utilized to create testing patterns of different frequencies such that a frequency response of the transmission line can be determined. Impedance mismatches resulting from manufacturing tolerances typically will not change over time, and thus, the tuning system 302 may only operate during power up or during a system configuration process, or periodically as desired.

A system will typically be designed for a specific data rate. To create pulses with different shapes and different lengths, different bit patterns can be requested from the transmitter 303 by the control module 328. For example, in one embodiment the test pulses can include a progression of transmitted bits as follows; 0-1-0-1, or 00-11-00-11 or, 000-111-000-111. Each of theses bit patterns has a longer pulse duration. In another embodiment a test pattern of bits such as 00000000001111111111 can be transmitted. Such a large pulse may be useful when the transmission line is long and it takes a long time for the reflection to return from the mismatch.

In yet another embodiment tuning can be achieved without a special interconnection of the tuning system to the transmitter or receiver. In this embodiment, the impedance measurement can be done in a two-step process. First, the transmitter tuning termination resistors 314 and 316 can be utilized as isolators where there resistance value is set high to essentially “remove” the transmitter impedance from the system 300. After isolating the transmitter impedance from the system, a current pulse can be drawn through the receiver 304 to determine a termination impedance of the receiver 304 and the voltage measurement taken by the compare module 328 can be stored. The transistors 310 and 312 can provide the test current pulse responsive to control signals on their gates “rect” and “rectb.” A rectangular current pulse can be sent to the receiver and the termination resistance measurement of the receiver can be taken at an appropriate time after the pulse reaches a steady state. Such a measurement with an infinite transmitter termination impedance will neglect the first order of the transistor output impedance of the transmitter 303 however; the majority of this impedance will typically be reactive.

In a second step, the transmitter termination resistors 314 and 316 can be “re-connected” and a second step pulse having twice the current can be provided by the differential pair 313. The current source 320 that controls the differential pair 313 can be controlled by the control module 322. As stated above the second pulse can pull twice the current as the first pulse and the voltage on the transmission line can be determined by the compare module 328 after the second step pulse. It can be determined that the impedance is at an acceptable level when the voltage responsive to the second pulse is equal to the voltage measured in response to the first pulse. Utilizing the equation Voltage=Current×Resistance, when the current is double and the resistance becomes half the original value (equivalent termination resistances of the transmitter and its tuning elements in parallel with the receiver and its tuning elements) in the consecutive tests, it can be confirmed that transmitter termination impedance and the receiver termination impedance are equal.

In one embodiment, after the transmitter termination resistance 314 and 316 is set to “infinity” the current sink 320 can be adjusted by the control module 322 until the compare module 328 trips to provide a measurement of the receiver termination resistance. The current sunk by the current sink 320 can be doubled, and the termination resistances 314 and 316 can be adjusted until the compare module 328 switches. This can ensure that the transmitter termination impedance matches the receiver termination impedance (including the tuning elements) because at the same voltage drop with half oft the resistance (two resistances in parallel) will draw twice the current.

Alternately described, elements 316 and 314 can be set to an infinite impedance and the differential pair 313 can be utilized to draw equal currents from each of the data lines of the receiver 304 such that the compare module 328 can measure the resistive impedance termination of the receiver 304. The control module 322 can control the amount of current that is sunk by the current sink 320 and utilizing the equation: resistance=voltage/current a relative measurement of the termination resistance of the receiver can be determined.

In yet other embodiments, the tuning system 302 can be utilized to determine the transmission line length, and can measure other transmission line parameters and imperfections and the location of such imperfections. The length of the channel can be determined utilizing the formula; distance=(velocity×time) where the velocity of the wave propagation is known and the time can be determined.

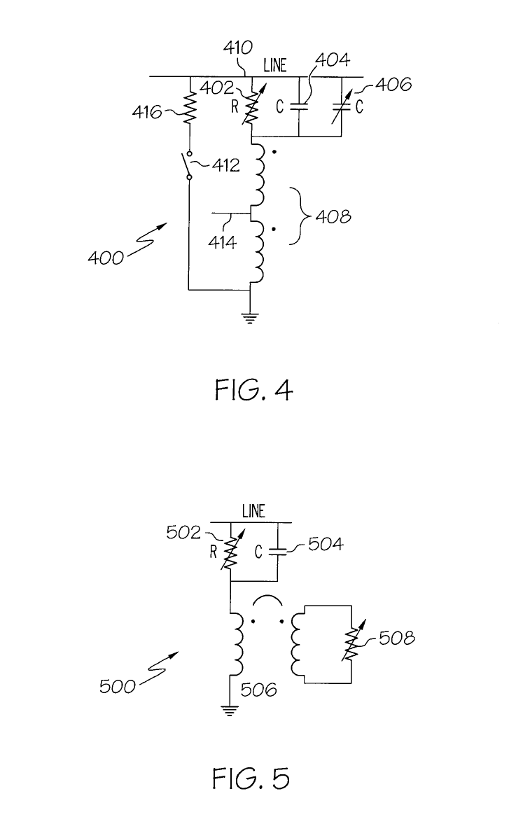

Referring to FIG. 4 a tunable resistive/reactive element 400 is depicted. The resistive/reactive element 400 can include a variable resistor 416 that is activated by a switch 412, an adjustable resistor 402, a capacitor 404, an adjustable capacitor 406, and a variable inductor 408. Such a structure is commonly referred to as a “T-Coil” structure with a series resistor 416 which can be designed to provide a variable resistance. The T-coil can be set to resonate to provide the desired load capacitance and adjustable resistor can provide the desired resistance.

If the capacitance supplied by capacitor 404 is smaller than the desired load capacitance for the transmission line, then an additional adjustable capacitance 406 can be controlled by a logic module to add additional capacitance to the transmission path and the system can achieve the desired load capacitance. The loading capacitance and the loading resistance can be adjusted either digitally by turning a switch that couples the capacitances or resistor to ground on and off or in an analog fashion by a gate voltage of a variable capacitor (“varactor”) structure or by biasing a transistor. The switch and biasing transistor can be implemented with a field effect transistor controlled by the logic module

Referring to FIG. 5 a tunable termination circuit 500 that has an adjustable inductance is disclosed. The tunable termination circuit 500 can include a variable resistor 502 in parallel with a capacitor 504 and a tunable transformer 506 in series with the resistor 502 and capacitor 504. The secondary winding of the tunable transformer 506 can have a variable resistor 508. The inductance provided by the tunable termination circuit 500 can be controlled by controlling the short-circuit resistance provided by resistor 508 in the secondary loop of transformer 506. Many methods could be utilized to provide such variable resistors, transistors, capacitors and inductors including micro-electro mechanical systems (MEMS).

Another embodiment may have two inductors where the “trimable” inductor element could have a lower Q value such that the trimable inductor will have a lesser effect on the total reactance. Thus, the reactance of the larger inductor will dominate in this circuit. In this configuration the main inductor could be a spiral inductor and the trimming element could be a C-MOS high Q wide tuning range active inductor. In a parallel configuration where the trimable components are connected in parallel, electrostatic discharge current paths could be connected separate from the adjustable section.

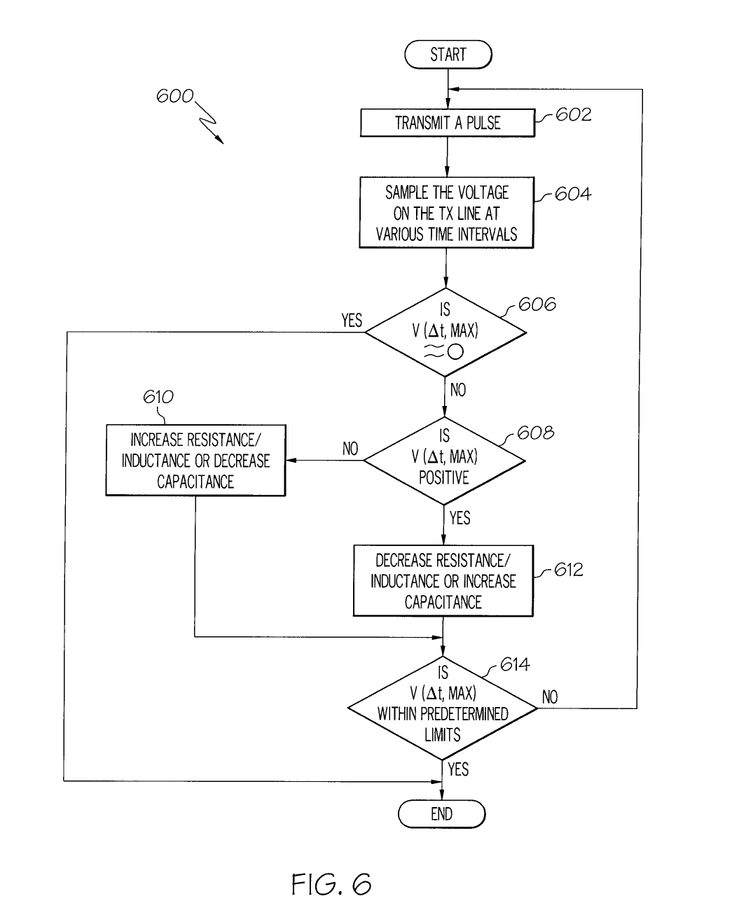

FIG. 6 is a flow diagram 600, that illustrates a method for tuning a transmission line by adding or subtracting resistive and reactive components to eliminate impedance mismatches on a transmission line. The process can be started by transmitting a pulse along a transmission line, as illustrated by block 602. The pulse can be reflected off of impedance mismatches possibly off of a termination at a receiver circuit. As illustrated by block 604, the voltage on the transmission line can be sampled at various times. A maximum deflection of the pulsed voltage due to the reflected wave can be determined when the appropriate number of samples are taken.

As illustrated by decision block 606, the maximum reflected power can be determined by the system and if the system determines that the maximum reflected power is close to zero, or less than a predetermined value, the process can end. When, as illustrated by decision block 606, the deflection of the pulse is greater than the predetermined value then it can be determined if the reflected energy increases the voltage of the pulse, as illustrated by block 608. When the voltage of the pulse is increased, or a positive voltage change to the pulse occurs, then, as indicated by block 612 the resistance or capacitance can be decreased by controlling a tuning element and/or the inductance can be increased. As disclosed with reference to the graph of FIG. 2, detection of a notch by the system could activate tuning of a reactance (capacitance or inductance) element and detection of a reflection of longer duration could be utilized to activate the tuning of a resistive portion of the tuning element.

When, as illustrated by decision block 608, there is not a positive shift in the pulse voltage due to the reflected energy, but there is a negative shift in the pulse voltage, then the resistance or the capacitance can be increased and/or the inductance of the tuning element can be decreased as illustrated by block 610. After such adjustments have been made it can be determined, as illustrated by decision block 614, if the change in pulse voltage due to the reflected energy is below a predetermined value. If the reflected energy is below a predetermined value, the process can end. If the reflected energy is not below a predetermined value then the process can return to block 602 where another pulse can be transmitted and the process can reiterate unit a successful match is achieved.

As stated above the reflection due to a resistive mismatch can be determined by measuring the maximum distortion possible near the end of the pulse duration (assuming the pulse with is chosen based on the length of the transmission line). The actual timing of the sample can be controlled by a programmable timer and the voltage level can be determined by a sampling comparator fed by an offset voltage. Time-voltage samples can be taken on numerous pulses and based on the determined attributes a control module can tune and re-tune tuning elements and can utilize past data to determine what changes should be made before another pulse test is attempted.

In one embodiment, the termination resistance of the transmitter can be adjusted by switching a transistor that interconnects different resistors in a resistor ladder. The output impedance of the transmitter can also be tuned by biasing or turning on a transistor. Such tuning process can utilize the same method described above for tuning the receiver termination where the transmitter and the receiver can exchange roles. One special application may arise, where a communication link that is configured in a full-duplex configuration. In such a configuration, the transmitter and receiver can share the same wires. In a full duplex system a small test transmitter, can be implemented that is able to generate a step function, with the described sampling apparatus integrated at the receiver termination. Since the proposed sampling apparatus can be implemented with minimal components on a relatively small space on an integrated circuit, the sampling apparatus can be easily integrated into a system on a chip.

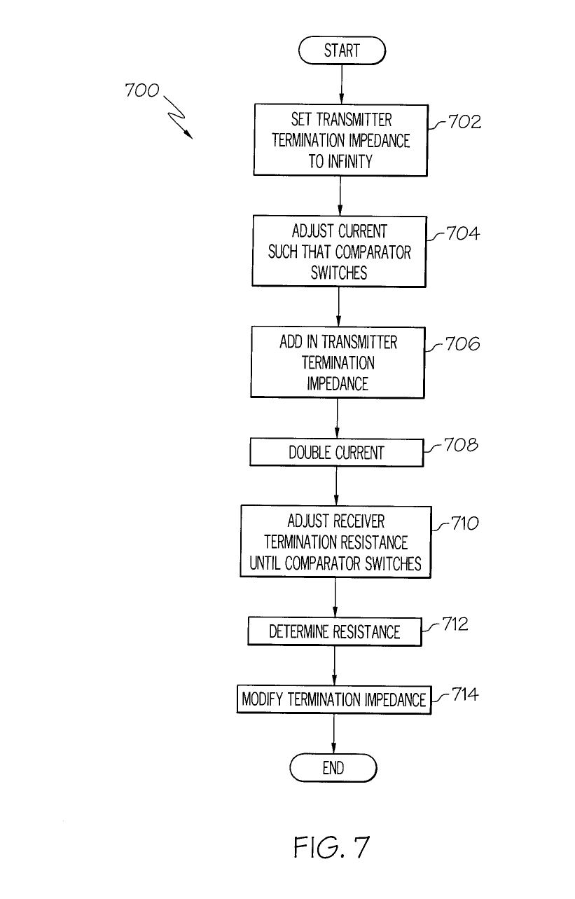

Referring to FIG. 7, an alternate method for tuning a transmission path is disclosed. As illustrated by block 702, a receiver termination resistance can be set to infinity, set to a high resistance value or removed from the circuit by a control module. A current through the termination resistors can be adjusted until a comparator switches, such that a resistance of the receiver termination can be detected or determined, as illustrated by block 704.

The transmitter impedance can be added back into the system, or switched back in as illustrated by block 706. The control module can control a current source to double the current on the transmission line as illustrated by blocks 708. Such a change in current can be accomplished by a control module controlling a switch and a current sink. The receiver termination impedance can be adjusted by the control module until the comparator switches as illustrated by block 710. Based on the trip point of the comparator, the resistance of the transmitter can be determined as illustrated by block 712.

Based on the measurement of the transmitter resistance and the receiver resistance, a control module can tune the system as illustrated by block 714 and the process can end. In another embodiment the receiver impedance can be set to infinity and the transmitter impedance can be determined such that the transmitter end of the system is tuned in accordance with the flow diagram 700.

Each process disclosed herein can be implemented with a software program. The software programs described herein may be operated on any type of computer, such as personal computer, server, etc. Any programs may be contained on a variety of signal-bearing media. Illustrative signal-bearing media include, but are not limited to: (i) information permanently stored on non-writable storage media (e.g., read-only memory devices within a computer such as CD-ROM disks readable by a CD-ROM drive); (ii) alterable information stored on writable storage media (e.g., floppy disks within a diskette drive or hard-disk drive); and (iii) information conveyed to a computer by a communications medium, such as through a computer or telephone network, including wireless communications. The latter embodiment specifically includes information downloaded from the Internet, intranet or other networks. Such signal-bearing media, when carrying computer-readable instructions that direct the functions of the present invention, represent embodiments of the present disclosure.

The disclosed embodiments can take the form of an entirely hardware embodiment, an entirely software embodiment or an embodiment containing both hardware and software elements. In a preferred embodiment, the invention is implemented in software, which includes but is not limited to firmware, resident software, microcode, etc. Furthermore, the invention can take the form of a computer program product accessible from a computer-usable or computer-readable medium providing program code for use by or in connection with a computer or any instruction execution system. For the purposes of this description, a computer-usable or computer readable medium can be any apparatus that can contain, store, communicate, propagate, or transport the program for use by or in connection with the instruction execution system, apparatus, or device.

The control module can retrieve instructions from an electronic storage medium. The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk-read only memory (CD-ROM), compact disk-read/write (CD-R/W) and DVD. A data processing system suitable for storing and/or executing program code can include at least one processor, logic, or a state machine coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards, displays, pointing devices, etc.) can be coupled to the system either directly or through intervening I/O controllers. Network adapters may also be coupled to the system to enable the data processing system to become coupled to other data processing systems or remote printers or storage devices through intervening private or public networks. Modems, cable modem and Ethernet cards are just a few of the currently available types of network adapters.

It will be apparent to those skilled in the art having the benefit of this disclosure that the present invention contemplates methods, systems, and media that can automatically tune a transmission line. It is understood that the form of the invention shown and described in the detailed description and the drawings are to be taken merely as examples. It is intended that the following claims be interpreted broadly to embrace all the variations of the example embodiments disclosed.

What is claimed is:

1. A method for configuring a communication system comprising:
transmitting electrical energy on a transmission path;
detecting reflected energy resulting from the transmitted electrical energy reflecting off of at least one impedance mismatch in the transmission path;
determining a characteristic of the reflected energy; and
automatically adjusting an impedance of the transmission path proximate to the impedance mismatch responsive to the determined characteristic of the reflected energy.

2. The method of claim 1, wherein the electrical energy is a pulse with a predetermined pulse duration such that the reflected energy returns prior to the end of the duration and alters a voltage of the pulse such that a voltage deflection can be determined.

3. The method of claim 2, wherein the voltage detection comprises detecting a maximum deflection voltage of the pulse.

4. The method of claim 1, wherein automatically adjusting comprises automatically adjusting a variable resistor coupled to the transmission path.

5. The method of claim 1, wherein automatically adjusting comprises adjusting a reactance of a variable reactor coupled to the transmission path or adjusting a state of a miniature electro-mechanical system (MEMS).

6. The method of claim 1, wherein automatically adjusting the reactance comprises automatically adjusting one of an inductive element or a capacitive element.

7. The method of claim 1, wherein the electrical energy is a pulse with a predetermined pulse duration such that during the pulse duration a reactive reflection can be detected.

8. The method of claim 1, further comprising identifying a frequency of the electrical energy transmitted on the transmission path that creates a maximal return signal.

9. The method of claim 1, further comprising determining the distance from a first point to the at least one impedance mismatch such that the determined characteristic occurs at a time that corresponds to the distance utilizing known information for the propagation velocity of the energy within the transmission path.

10. A communication system comprising:
an isolator to decouple a first adjustable resistive load from a transmission path in a first mode and to couple the first adjustable resistive load to the transmission path in a second mode;
a test transmitter to create a first current on the transmission path in the first mode and to create a second current on the transmission path in a second mode, wherein the second current is approximately twice the first current;
a detector coupled to the transmission path to detect a first voltage on the transmission path during the first mode in response to the first current and to detect a second voltage substantially similar to the first voltage responsive to the second current in the second mode; and
a control logic module responsive to the detector to adjust a resistance of the first adjustable resistive load during the second mode.

11. The communication system of claim 10, further comprising:
a tunable impedance module coupled to the transmission path and the control logic module to accept control signals from the control logic module and change a reactance of at least a portion of the transmission path responsive to detection of reflected signal energy by the detection module on the transmission path resulting from a test signal.

12. The communication system of claim 11, wherein the tunable impedance module comprises a T-coil having an adjustable capacitance to tune out a reactive component of the second termination.

13. The communication system of claim 10, further comprising an integrator coupled to the transmission path and to the detection module to average a magnitude of reflected signal energy.

14. The communication system of claim 10, wherein a resistance of the first adjustable resistive load is modified by the control logic module responsive to a detected magnitude of the reflected signal energy.

15. A communication system comprising:
a transmission line;
a transmitter to transmit electrical energy over the transmission line;
a detector coupled to the transmission line to detect reflected energy resulting from the transmitted energy;
a control logic module coupled to the detector to determine an impedance change in the transmission line based on parameters of the reflected energy; and
a tunable impedance module coupled to the control logic and the transmission line to automatically change a termination impedance of the transmission line responsive to the determined impedance change in the transmission line.

16. The system of claim 15, further comprising a receiver termination to create the impedance change and to absorb at least a portion of the electrical energy.

17. The system of claim 15, further comprising a test transmitter located proximate to the receiver and a second tunable impedance module coupled proximate to the transmitter wherein the second tunable impedance module can change the impedance of a device proximate to a transmitter end of the transmission line based on a reflected signal from the test transmitter.

18. The system of claim 15, wherein the tunable impedance module comprises a tunable inductor.

19. The system of claim 15, wherein the tunable impedance module comprises a switch to switch from a first impedance value to a second impedance value.

20. The system of claim 15, wherein the tunable impedance module is one of a tunable capacitor or a tunable impedance module.

21. A method of tuning a circuit comprising:
increasing an impedance of a first termination impedance to limit a first current to flow through the first termination impedance;
providing a second current through a second termination impedance and detecting a first voltage associated with the second current;
changing the value of the first termination impedance;
providing a third current which is a combined current through the first and second termination impedances;
detecting a second voltage responsive to the third current; and
adjusting the value of the first termination impedance such that the second voltage substantially matches the first voltage.
